(19) United States
(12) Patent Application Publication
(10) Pub. No.: US 2012/0025279 A1
(43) Pub. Date: Feb. 2, 2012

(54) LOW SCHOTTKY BARRIER SEMICONDUCTOR STRUCTURE AND METHOD FOR FORMING THE SAME

(75) Inventors: Jing Wang, Beijing (CN); Wei Wang, Beijing (CN); Lei Guo, Bejing (CN); Jun Xu, Beijing (CN)

(73) Assignee: TSINGHUA UNIVERSITY, Beijing (CN)

(21) Appl. No.: 13/132,760

(22) PCT Filed: May 10, 2011
(86) PCT No.: PCT/CN2011/073904

§ 371 Date: Jun. 3, 2011

(30) Foreign Application Priority Data
May 26, 2010 (CN) 201010183119.9

(51) Int. Cl. H01L 29/812; H01L 21/338

(52) U.S. Cl. 257/280; 438/167; 257/E29.317; 257/E21.45

(57) ABSTRACT

A low Schottky barrier semiconductor structure is provided, comprising: a substrate; a SiGe layer with low Ge content formed on the substrate; a channel layer with high Ge content formed on the SiGe layer; a gate stack formed on the substrate and a side wall of one or more layers formed on both sides of the gate stack; a metal source and a metal drain formed in the channel layer and on the both sides of the gate stack respectively; and an insulation layer formed between the substrate and the metal source and between the substrate and the metal drain respectively.

### FIELD

The present disclosure relates to semiconductor manufacture and design, and more particularly to a low Schottky barrier semiconductor structure and a method for forming the same.

### BACKGROUND

A development of a conventional Si-channel transistor is challenged by two major problems: a maximum saturation current limit due to a hot carrier injection from a source or a channel to a gate dielectric layer or a substrate, and a leakage due to a fact that a sub-threshold characteristic does not change with a scaling down of the transistor. An introduction of a non-Si channel material in a semiconductor field is considered important in improving a transistor performance. Since Ge material has a better low-field mobility and a less band gap than Si material and a production process of a Ge channel device is compatible with that of a conventional Si transistor, Ge channel material is considered as a promising alternative to Si channel material. The two above problems may be alleviated and solved to a certain degree by replacing the Si channel material with the Ge channel material. However, a conventional field effect transistor with Ge as the channel material still has the following problems such as a BTBT (Band To Band Tunneling) interband leakage caused by a narrow bandgap, a poor interface between a Ge substrate and a gate dielectric layer, extremely low activation rate at a drain and a source, a large junction depth due to an extremely easy diffusion of a dopant at a high temperature.

In particular, a fabrication of a source and a drain in a Ge transistor may be affected by a solid solubility of the dopant in Ge, a diffusion coefficient and a melting point of the Ge material, so that it is difficult to achieve a high activation rate of the dopant and an ultra-shallow junction depth, which is very unfavorable for a reduction of a MOS device size. Therefore, how to form the source and the drain in the Ge transistor has become a focus.

### SUMMARY

The present disclosure is aimed to solve at least one of the above mentioned technical problems, particularly a defect of being difficult to form a source and a drain in a Ge transistor.

According to an aspect of the present disclosure, a low Schottky barrier semiconductor structure is provided, comprising: a substrate; a SiGe layer with low Ge content formed on the substrate; a channel layer with high Ge content formed on the SiGe layer; a gate stack formed on the substrate and a side wall of one or more layers formed on both sides of the gate stack; a metal source and a metal drain formed in the channel layer and on the both sides of the gate stack respectively; and an insulation layer formed between the substrate and the metal source and between the substrate and the metal drain respectively.

In one embodiment, the channel layer with high Ge content comprises a Ge channel layer or a SiGe channel layer with high Ge content.

In one embodiment, the low Schottky barrier semiconductor structure further comprises: a Si layer or a SiGe layer with low Ge content formed on the channel layer, forming a Si—Ge—Si structure on the substrate.

In one embodiment, the insulation layer is a silicon nitride layer or a germanium nitride layer.

In one embodiment, the insulation layer has a thickness ranging from 0.3 nm to 5 nm.

According to another aspect of the present disclosure, a method for forming a low Schottky barrier semiconductor structure is provided, comprising steps of: providing a substrate; forming a SiGe layer with low Ge content on the substrate; forming a channel layer with high Ge content on the SiGe layer; forming a gate stack on the substrate and forming a side wall of one or more layers on both sides of the gate stack; forming a source trench and a drain trench by etching the substrate and by using the gate stack and the side walls as a mask; forming an insulation layer in the source trench and in the drain trench; and forming a metal source and a metal drain on the insulation layer in the source trench and the drain trench respectively.

In one embodiment, the channel layer with high Ge content comprises a Ge channel layer or a SiGe channel layer with high Ge content.

In one embodiment, the method for forming a low Schottky barrier semiconductor structure further comprises a step of: forming a Si layer or a SiGe layer with low Ge content on the channel layer to form a Si—Ge—Si structure on the substrate.

In one embodiment, the insulation layer is a silicon nitride layer or a germanium nitride layer.

In one embodiment, the insulation layer has a thickness ranging from 0.3 nm to 5 nm.

According to an embodiment of the present disclosure, since the insulation layer is formed between the substrate and the metal source and between the substrate and the metal drain respectively, a gap state caused by the metal source and the metal drain may be prevented from getting into the channel, thus eliminating a Fermi level pinning effect, reducing a Schottky barrier height and increasing an on/off current ratio of the transistor. In one preferred embodiment, a Si—Ge—Si structure may also be formed on the substrate, which may not only alleviate problems of a BTBT leakage and a surface state at an interface between the gate dielectric layer and the channel, but also form a hole barrier, thus improving the device performance. In some embodiments of the present disclosure, a source and drain implanting and a halo implanting are no longer needed during the process, thus not only increasing the on/off current ratio of the Ge transistor and effectively alleviating the leakage of the Ge transistor, but also reducing the fabricating cost of the transistor.

Additional aspects and advantages of the embodiments of the present disclosure will be given in part in the following descriptions, become apparent in part from the following descriptions, or be learned from the practice of the embodiments of the present disclosure.

### BRIEF DESCRIPTION OF THE DRAWINGS

These and other aspects and advantages of the disclosure will become apparent and more readily appreciated from the following descriptions taken in conjunction with the drawings in which:

FIG. 1 is a cross-sectional view of a low Schottky barrier semiconductor structure according to an embodiment of the present disclosure;

FIG. 2 is a cross-sectional view of a low Schottky barrier semiconductor structure with a Si—Ge—Si structure according to an embodiment of the present disclosure; and

FIGS. 3-8 are cross-sectional diagrams of intermediate statuses of a low Schottky barrier semiconductor structure formed during a process of a method for forming the low Schottky barrier semiconductor structure according to an embodiment of the present disclosure.

### DETAILED DESCRIPTION OF EMBODIMENTS OF THE DISCLOSURE

Embodiments of the present disclosure will be described in detail in the following descriptions, examples of which are shown in the accompanying drawings, in which the same or similar elements and elements having same or similar functions are denoted by like reference numerals throughout the descriptions. The embodiments described herein with reference to the accompanying drawings are explanatory and illustrative, which are used to generally understand the present disclosure. The embodiments shall not be construed to limit the present disclosure.

Various embodiments and examples are provided in the following description to implement different structures of the present disclosure. In order to simplify the present disclosure, certain elements and settings will be described. However, these elements and settings are only examples and are not intended to limit the present disclosure. In addition, reference numerals may be repeated in different examples in the disclosure. This repeating is for the purpose of simplification and clarity and does not refer to relations between different embodiments and/or settings. Furthermore, examples of different processes and materials are provided in the present disclosure. However, it would be appreciated by those skilled in the art that other processes and/or materials may be also applied. Moreover, a structure in which a first feature is “on” a second feature may include an embodiment in which the first feature directly contacts the second feature and may include an embodiment in which an additional feature is prepared between the first feature and the second feature so that the first feature does not directly contact the second feature.

According to an embodiment of the present disclosure, a Schottky contact is formed between the metal source and the semiconductor substrate and between the metal drain and the semiconductor substrate respectively. Since a Schottky junction has a rectifying characteristic, a conductive channel will be formed below a transistor gate at a suitable gate voltage and a source drain bias voltage, so that carriers may be emitted from the metal source to the channel and then may transport in the channel. In some embodiments of the present disclosure, the transistor of this structure has the following advantages.

(1) A source and drain implanting and a halo implanting are no longer needed, thus greatly simplifying a fabrication process of the transistor and reducing damage to the substrate caused by a high-concentration implanting.

(2) The process does not involve an activation and a diffusion of a dopant in the source and the drain, and there is no high-temperature process during the whole fabrication process, which makes it possible to complete the fabrication of a high-k metal gate structure and an introduction of a channel stress without using a Gate-Last process, thus facilitating further exploring a potential of a Ge channel device.

(3) A PN junction structure is no longer needed, thus substantially eliminating a Latch-up effect, simplifying an isolation process of the transistor and increasing chip integrity.

However, since a metal induced gap state (MIGS) is introduced at an interface between the germanium and a conventional germanide (e.g., NiGe, TiGe, CoGe), the Fermi level in the germanium will be pinned, and a strong Fermi level pinning will cause an energy level of the germanium to be fixed. In most cases, this would form a high Schottky barrier to hinder carrier transport. In order to alleviate this problem, in some embodiments of the present disclosure, an insulation layer is formed between the metal source and the semiconductor substrate and between the metal drain and the semiconductor substrate respectively. The insulation layer may be a SiN (silicon nitride) layer or a GeN (germanium nitride) layer, which may prevent a free state of the metal in the source and the drain from entering the Ge channel, thus releasing the Fermi level pinning, effectively reducing the Schottky barrier height, and reducing the impact of the MIGS on the channel region. Meanwhile, since there are auxiliary carrier tunneling defects at an interface between the selected insulation material and the channel, the insulation layer is very thin itself and the thermal field emission gives the carriers sufficient energy so that the carriers may tunnel in and out of the channel by passing through the insulation layer. Therefore, according to an embodiment of the present disclosure, the Fermi level pinning of Ge may be effectively released, and the Schottky barrier height may be reduced.

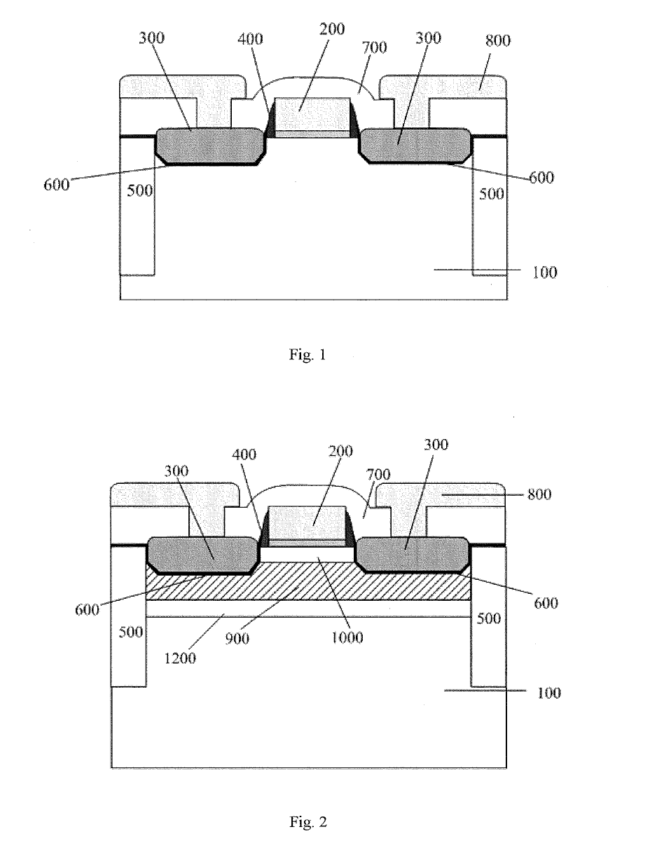

FIG. 1 is a cross-sectional view of a low Schottky barrier semiconductor structure according to an embodiment of the present disclosure. The low Schottky barrier semiconductor structure comprises: a substrate 100; a gate stack 200 formed on the substrate 100 and a side wall 400 of one or more layers formed on both sides of the gate stack 200; and an isolation structure 500 for isolation. The substrate 100 may be of Si, SiGe with low Ge content, group materials, group II-VI materials or other semiconductor materials. In one embodiment, the isolation structure 500 may comprise a STI isolation structure or a LOCOS isolation structure. Certainly, other isolation structures may also be selected by those skilled in the art. In another embodiment, the gate stack 200 may comprise a gate dielectric layer and a gate, and preferably may comprise a high-k gate dielectric layer and a metal gate. Certainly, the dielectric layer of other oxides, and the gate of polycrystalline silicon may also be used, which should also fall within the scope of the present disclosure. In some embodiments of the present disclosure, because of using the metal source and the metal drain, an annealing for the source and drain dopant activation may not be needed, thus avoiding the high temperature process. Therefore, the fabrication of the high-k gate dielectric layer, the metal gate and the channel may be completed without using a gate-last process.

The low Schottky barrier semiconductor structure may also comprise a metal source 300 and a metal drain 300 formed on the both sides of the gate stack 200 respectively and in the substrate 100; and an insulation layer 600 formed between the substrate 100 and the metal source 300 and between the substrate 100 and the metal drain 300. In one embodiment, the metals for forming the source 300 and the drain 300 may include, but are not limited to, Al, Cu, Pt, Ni, W, Er, Ti, Yb, other conventional metals, or other rare earth metals. In another embodiment, the insulation layer 600 may be a SiN layer or a GeN layer. In the above embodiments, the thickness of the insulation layer 600 may vary according to the materials in the barrier layer and in the metal source 300 and the metal drain 300. In some embodiments, the insulation layer 600 may have a thickness ranging from about 0.3 nm to 5 nm. In some embodiments of the present disclosure, the thickness of the insulation layer 600 is very important. If the insulation layer 600 is too thin, the gap state may not be blocked sufficiently; and if the insulation layer 600 is too thick, it will be difficult for the carriers to tunnel, which are unfavorable for an increment of an on-state current. In one embodiment, if the insulation layer 600 is a SiN layer and the source and the drain are of Al, the insulation layer 600 may preferably have a thickness of about 3 nm.

In one embodiment, the low Schottky barrier semiconductor structure may also comprise a dielectric layer 700, and a contact hole and a metal line 800 connected with the metal source 300 and the metal drain 300 respectively.

In one preferred embodiment, a Si—Ge—Si structure may also be used to alleviate problems of the BTBT leakage and the surface state at the interface between the gate dielectric layer and the channel. For example, in one embodiment, as shown in FIG. 2, a Si substrate 100 may be used, and a channel layer 900 with high Ge content may be formed on the substrate 100, in which the metal source 300 and the metal drain 300 may be formed in the channel layer 900 with high Ge content respectively. The channel layer 900 with high Ge content may comprise a Ge channel layer or a SiGe channel layer with high Ge content. It should be noted that, in some embodiments of the present disclosure, high Ge content and low Ge content are merely relative concepts. Herein, the term “high Ge content” means that the content of Ge in the SiGe layer is greater than 30%, and the term “low Ge content” means that the content of Ge in the SiGe layer is less than 30%. When the substrate 100 is of materials other than Si, a Si layer or a SiGe layer with low Ge content may be formed on the substrate 100.

In other embodiments, the low Schottky barrier semiconductor structure may also comprise a Si layer 1000 formed on the channel layer 900 with high Ge content to form a Si—Ge—Si structure. It should be noted that the Si—Ge—Si structure described above may be formed by various methods. For example, in one embodiment, a SiGe layer with low Ge content may be first formed on the Si substrate, then a layer with high Ge content may be formed on the SiGe layer with low Ge content, and finally a Si layer may be formed on the layer with high Ge content, thus forming the Si—Ge—Si structure. In another embodiment, the content of Ge in the SiGe layer may be controlled to form the Si—Ge—Si structure.

In order to better understand the semiconductor structure according to an embodiment of the present disclosure, a method for forming the semiconductor structure described above is also provided. It should be noted that the semiconductor structure may be fabricated through various technologies, such as different types of product lines or different processes. However, if the semiconductor structures fabricated through various technologies have substantially the same structure and technical effects as those of the present disclosure, they should be within the scope of the present disclosure. In order to better understand the present disclosure, the method for forming the semiconductor structure of the present disclosure described above will be described in detail below. Moreover, it should be noted that the following steps are described only for exemplary and/or illustration purpose rather than for limitations. Other technologies may be adopted by those skilled in the art to form the semiconductor structure of the present disclosure described above.

The method for forming a low Schottky barrier semiconductor structure will be described below taking the Si—Ge—Si structure as an example. For examples not using the Si—Ge—Si structure, those skilled in the art may refer to the following embodiments, so detailed description thereof will be omitted here.

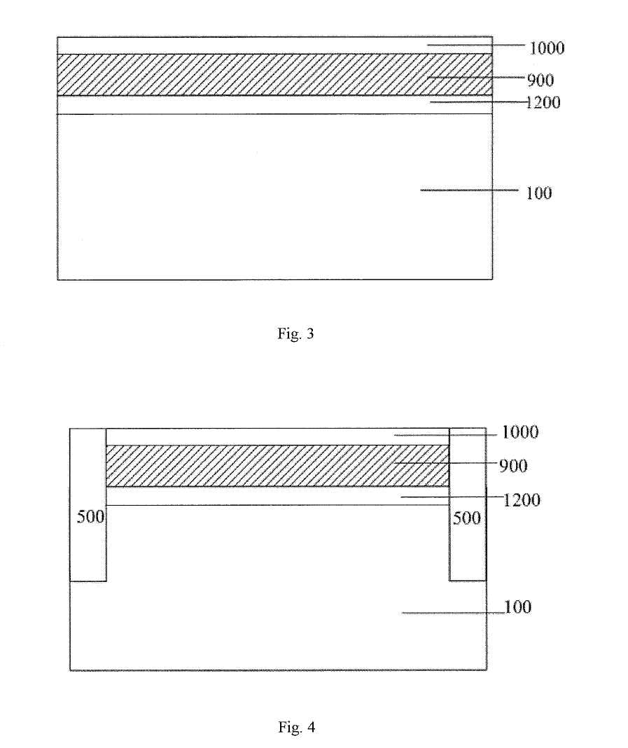

FIGS. 3-8 are cross-sectional diagrams of intermediate statuses of a low Schottky barrier semiconductor structure formed during a process of a method for forming the low Schottky barrier semiconductor structure according to an embodiment of the present disclosure. The method may comprise the following steps.

Step S101, the substrate 100 is provided. In this embodiment, the substrate 100 is a Si substrate or a SiGe substrate with low Ge content. In other embodiments, a SiGe layer with low Ge content may also be formed on the substrate 100.

Step S102, the channel layer 900 with high Ge content is formed on the substrate 100. If the SiGe layer with low Ge content is formed on the substrate 100 in Step S101, the channel layer 900 with high Ge content is formed on the SiGe layer with low Ge content. In one embodiment, the channel layer 900 with high Ge content may be a Ge channel layer or a SiGe channel layer with high Ge content, and a Si layer or a SiGe layer 1000 with low Ge content is formed on the channel layer 900 with high Ge content again to form the Si—Ge—Si structure, as shown in FIG. 3. More particularly, in one embodiment, for example, the SiGe substrate 100 with low Ge content may be provided, and then a Si layer 1200 with a thickness of about 3 nm is formed thereon by chemical vapor deposition, and then a Ge layer 900 having a thickness of about 6 nm and doped with boron at a concentration of 1×10¹⁴/cm³ is formed on the Si layer 1200, and finally a Si layer 1000 with a thickness of about 3 nm is formed on the Ge layer 900 to form the Si—Ge—Si structure.

Step S103, an active region is defined, and the isolation structure 500 is fabricated, as shown in FIG. 4.

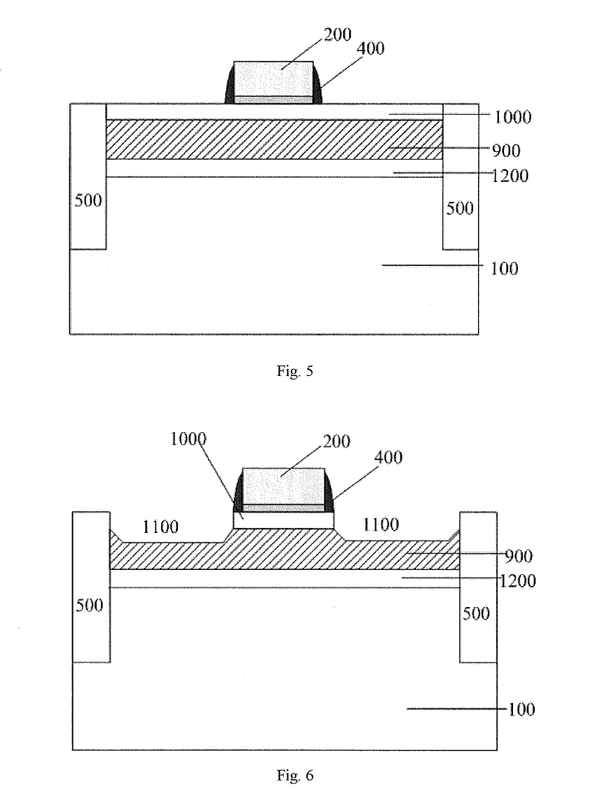

Step S104, the gate stack 200 is formed on the Si layer 1000, and the side walls 400 are formed on both sides of the gate stack 200, as shown in FIG. 5. In one embodiment, the gate stack 200 may comprise a gate dielectric layer and a gate, and preferably may comprise a high-k gate dielectric layer and a metal gate. Certainly, the dielectric layer of other nitrides or oxides, and the gate of polycrystalline silicon may also be used, which should also fall within the scope of the present disclosure. In some embodiments of the present disclosure, because of using the metal source and the metal drain, an annealing for the source and drain dopant activation may not be needed, thus avoiding the high temperature process. Therefore, the fabrication of the high-k gate dielectric layer, the metal gate and the channel may be completed without using a gate-last process.

Step S105, the Si layer 1000 and the channel layer 900 with high Ge content are etched using the gate stack 200 and the side walls 400 as a mask to form a source trench 1100 and a drain trench 1100 respectively, as shown in FIG. 6. It should be noted that a shape of the source trench and the drain trench is merely exemplary, and any shape meeting requirements may be used by those skilled in the art, which may be within the scope of the present disclosure.

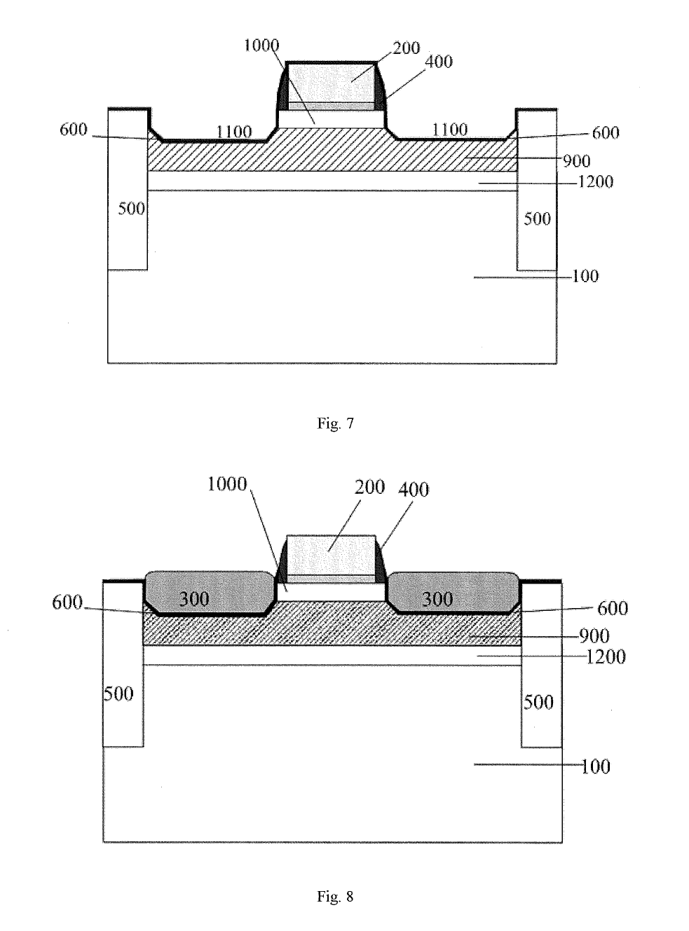

Step S106, the insulation layer 600 is deposited in the source trench 1100 and the drain trench 1100, as shown in FIG. 7. In another embodiment, the insulation layer 600 may be a SiN layer or a GeN layer, and may have a thickness ranging from about 0.3 nm to 5 nm.

In one embodiment, the insulation layer is preferably the GeN layer. Particularly, the GeN layer is formed by plasma ultra high vacuum chemical vapor deposition (UHV-CVD). For example, a surface of a Ge wafer is first cleaned in a UHV reaction furnace, and then the Ge wafer is heated to 300-600° C. under a pressure below about 10⁻¹⁰ Torr for about 3 to 5 minutes, to precipitate an impurity such as O or C on the surface of the trench 1100, thus improving a quality of the GeN insulation layer. Then, in the same furnace, an overall air pressure is controlled to be below about 15 mTorr, and a plasma nitrogen with a flow of about 20-100 sccm is passed into the furnace at a DC power of about 20-80 W. The temperature of the substrate 100 is within a range from room temperature to 300° C. for a reaction time of 5 to 30 minutes. In some embodiments of the present disclosure, the thickness of the formed GeN layer is controlled to range from about 0.3 nm to 5 nm. In one preferred embodiment, in a GeN UHV reaction furnace, under a pressure of 10⁻¹⁰ Torr at a temperature of 500° C., the surface of the wafer is cleaned for 3 minutes to remove the impurity such as O or C adsorbed on the surface of the trench 1100; then the plasma nitrogen with a flow of 60 sccm is passed into the reaction furnace at a DC power of 40 W, and the temperature of the substrate 100 is maintained at 200° C. for a reaction time of 10 minutes, thus forming the GeN layer with the thickness of about 2 nm.

In another embodiment, the SiN may be formed by plasma-enhanced chemical vapor deposition (PECVD). Particularly, the SiN with a thickness of about 0.3 nm to 5 nm may be formed under the following conditions: a NH₃/SiH₄ mixed gas with a flow ratio of about 5:1 to 15:1 is used as a precursor; the SiH₄ flow is about 5-15 sccm; a substrate temperature is maintained within a range from room temperature to 300° C.; a working pressure in a reaction furnace is about 30-200 Pa; and a reaction time is about 30-300 s. In one preferred embodiment, the SiN with a thickness of about 1.5 nm may be formed under the following conditions: a NH₃/SiH₄ mixed gas with a flow ratio of 10:1 is passed into a PECVD reaction furnace; the SiH₄ flow is about 10 sccm; a substrate temperature is maintained at 250° C.; a working pressure in a reaction furnace is about 66 Pa; and a reaction time is about 45 s.

Step S107, the source 300 and the drain 300 are formed on the insulation layer 600 in the source trench 1100 and the drain trench 1100 respectively, as shown in FIG. 8. For example, a layer of metal such as Al may be sputtered by using a physical vapor deposition method, then the metal on the gate stack 200 is removed by etching, and finally the source 300 and the drain 300 covering the insulation layer 600 are formed in the source region and the drain region respectively. In one embodiment, the metals for forming the source 300 and the drain 300 may include, but are not limited to, Al, Cu, Pt, Ni, W, Er, Ti, Yb, other conventional metals, or other rare earth metals.

Step S108, the dielectric layer 700 is deposited, and the contact hole and the metal line 800 connected with the metal source 300 and the metal drain 300 respectively are formed, as shown in FIG. 2.

According to an embodiment of the present disclosure, since the insulation layer is formed between the substrate and the metal source and between the substrate and the metal drain respectively, a gap state caused by the metal source and the metal drain may be prevented from getting into the channel, thus eliminating a Fermi level pinning effect, reducing a Schottky barrier height and increasing an on/off current ratio of the transistor. In one preferred embodiment, a Si—Ge—Si structure may also be formed on the substrate, which may not only alleviate problems of a BTBT leakage and a surface state at an interface between the gate dielectric layer and the channel, but also form a hole barrier, thus improving the device performance. In some embodiments of the present disclosure, a source and drain implanting and a halo implanting are no longer needed during the process, thus not only increasing the on/off current ratio of the Ge transistor and effectively alleviating the leakage of the Ge transistor, but also reducing the fabricating cost of the transistor.

Although explanatory embodiments have been shown and described, it would be appreciated by those skilled in the art that changes, alternatives, and modifications all falling into the scope of the claims and their equivalents may be made in the embodiments without departing from spirit and principles of the disclosure.

1. A low Schottky barrier semiconductor structure, comprising:
a substrate;
a SiGe layer with low Ge content formed on the substrate;
a channel layer with high Ge content formed on the SiGe layer;
a gate stack formed on the substrate and a side wall of one or more layers formed on both sides of the gate stack;
a metal source and a metal drain formed in the channel layer and on the both sides of the gate stack respectively; and
an insulation layer formed between the substrate and the metal source and between the substrate and the metal drain respectively.

2. The low Schottky barrier semiconductor structure according to claim 1, wherein the channel layer with high Ge content comprises a Ge channel layer or a SiGe channel layer with high Ge content.

3. The low Schottky barrier semiconductor structure according to claim 1, further comprising:
a Si layer or a SiGe layer with low Ge content formed on the channel layer, forming a Si—Ge—Si structure on the substrate.

4-10. (canceled)

11. The low Schottky barrier semiconductor structure according to claim 1, wherein the insulation layer is a silicon nitride layer or a germanium nitride layer.

12. The low Schottky barrier semiconductor structure according to claim 2, wherein the insulation layer is a silicon nitride layer or a germanium nitride layer.

13. The low Schottky barrier semiconductor structure according to claim 3, wherein the insulation layer is a silicon nitride layer or a germanium nitride layer.

14. The low Schottky barrier semiconductor structure according to claim 11, wherein the insulation layer has a thickness ranging from 0.3 nm to 5 nm.

15. The low Schottky barrier semiconductor structure according to claim 12, wherein the insulation layer has a thickness ranging from 0.3 nm to 5 nm.

16. The low Schottky barrier semiconductor structure according to claim 13, wherein the insulation layer has a thickness ranging from 0.3 nm to 5 nm.

17. A method for forming a low Schottky barrier semiconductor structure, comprising steps of:
providing a substrate;
forming a SiGe layer with low Ge content on the substrate;
forming a channel layer with high Ge content on the SiGe layer;
forming a gate stack on the substrate and forming a side wall of one or more layers on both sides of the gate stack;
forming a source trench and a drain trench by etching the substrate and by using the gate stack and the side walls as a mask;
forming an insulation layer in the source trench and in the drain trench; and
forming a metal source and a metal drain on the insulation layer in the source trench and the drain trench respectively.

18. The method according to claim 17, wherein the channel layer with high Ge content comprises a Ge channel layer or a SiGe channel layer with high Ge content.

19. The method according to claim 17, further comprising a step of:
forming a Si layer or a SiGe layer with low Ge content on the channel layer to form a Si—Ge—Si structure on the substrate.

20. The method according to claim 17, wherein the insulation layer is a silicon nitride layer or a germanium nitride layer.

21. The method according to claim 18, wherein the insulation layer is a silicon nitride layer or a germanium nitride layer.

22. The method according to claim 19, wherein the insulation layer is a silicon nitride layer or a germanium nitride layer.

23. The method according to claim 20, wherein the insulation layer has a thickness ranging from 0.3 nm to 5 nm.

24. The method according to claim 21, wherein the insulation layer has a thickness ranging from 0.3 nm to 5 nm.

25. The method according to claim 22, wherein the insulation layer has a thickness ranging from 0.3 nm to 5 nm.
